(19) United States
(12) Patent Application Publication
(10) Pub. No.: US 2006/0003534 A1
(43) Pub. Date: Jan. 5, 2006

(54) Salicide process using bi-metal layer and method of fabricating semiconductor device using the same

(75) Inventors: Kwan-Jong Roh, Anyang-si (KR); Min-Chul Sun, Suwon-si (KR); Ja-Hum Ku, Seongnam-si (KR); Sug-Woo Jung, Suwon-si (KR); Min-Joo Kim, Seoul (KR); Sung-Kee Han, Seoul (KR)

Correspondence Address: MILLS & ONELLO LLP, ELEVEN BEACON STREET, SUITE 605, BOSTON, MA, 02108, US

(73) Assignee: Samsung Electronics Co., Ltd.

(21) Appl. No.: 11/147,633

(22) Filed: Jun. 8, 2005

(30) Foreign Application Priority Data
Jun. 9, 2004 (KR) 04-42354

(51) Int. Cl. H01L 21/336

(52) U.S. Cl. 438/300

(57) ABSTRACT

A salicide process using a bi-metal layer and method of fabricating a semiconductor substrate using the same are disclosed herein. The salicide process includes forming a main metal layer on a semiconductor substrate containing silicon. A main metal alloy layer containing at least one species of alloy element is formed on the main metal layer. The semiconductor substrate having the main metal layer and the main metal alloy layer is annealed to form a main metal alloy silicide layer. According to an exemplary embodiment of the present invention, the main metal layer may be formed of a nickel (Ni) layer, and the main metal alloy layer may be formed of a nickel tantalum alloy layer. In this case, a nickel tantalum silicide layer having improved thermal stability and electrical characteristics are formed.

### CROSS-REFERENCE TO RELATED APPLICATION

This application claims the benefit of Korean Patent Application No. 2004-42354, filed Jun. 9, 2004, the contents of which are hereby incorporated herein by reference in their entirety.

### BACKGROUND OF THE INVENTION

1. Field of the Invention

The present invention relates to a salicide process and method of fabricating a semiconductor device using the same and, more particularly, to a salicide process using a bi-metal layer and method of fabricating a semiconductor device using the same.

2. Description of the Related Art

Semiconductor devices typically employ discrete devices such as MOS transistors used as switching devices. As the degree of integration of the semiconductor devices increases, the MOS transistors are scaled down. As a result, channel length of the MOS transistor is reduced, resulting in a short channel effect. As the channel length is reduced, width of the gate electrode is narrowed. Therefore, electrical resistance of the gate electrode increases. In order to improve the short channel effect, it is required to reduce thickness of the gate insulating layer as well as junction depth of source and drain regions of the MOS transistor. Eventually, both resistance and capacitance of the gate electrode are increased. In this case, transmission speed of electrical signals applied to the gate electrode is slowed due to RC-delay time (resistance-capacitance delay time).

In addition, the source and drain regions have a shallow depth, which increases their sheet resistance. As a result, drivability of the short channel MOS transistor is lowered. Therefore, in order to implement a high performance MOS transistor suitable for the VLSI semiconductor device, salicide (self-aligned silicide) technology has been widely used. The salicide technology is a process technology for reducing electrical resistance of the gate electrode and the source and drain regions by selectively forming a metal silicide layer on the gate electrode and the source and drain regions. The metal silicide layer generally employs titanium silicide (TiSi₂), cobalt silicide (CoSi₂) or nickel silicide (NiSi), etc.

The titanium silicide layer has advantages of relatively low specific resistance, strong resistance to hot carrier degradation in comparison with a polysilicon gate electrode, and stable silicidation reaction. However, there is a high probability of creating a short circuit between a gate and at least one of source and drain by lateral growth in forming the silicide and undesired reaction to an oxide layer used as a gate spacer. In addition, there is a problem that the sheet resistance is increased as a line width is reduced. The cobalt silicide layer has low specific resistance, high stability at high temperature and very low reactivity to an oxide layer. In addition, the resistance of the cobalt silicide layer has a very low dependency on changes of the line width. However, there is a drawback when the cobalt silicide layer is applied to the gate electrode due to a phenomenon referred to as “agglomeration”, when the gate electrode has a width less than about 0.1 μm. In addition, it is difficult to form the shallow junction due to much consumption of silicon.

Since the nickel silicide layer may be formed at a relatively low temperature, has no problem of an increase of the resistance due to a reduction of the line width, and has advantages of less consumption of silicon, the nickel silicide layer has been researched as the next generation metal silicide material. However, the nickel silicide layer has a problem of weak thermal stability. That is, the nickel silicide layer is formed of nickel mono-silicide (NiSi) having low specific resistance at about 300˜500° C. However, in the case of a temperature of about 600° C. or more, the resistance is increased due to a phase transformation from the nickel mono-silicide to nickel di-silicide (NiSi₂) and an agglomeration phenomenon. Therefore, the subsequent thermal process, i.e., a reflow process of an interlayer insulating layer such as a boro-phosphor-silicate glass (BPSG) layer, which is performed after forming the nickel silicide layer, is subjected to restriction.

As described above, the suicides have inherent disadvantages in spite of their advantages. In order to overcome the aforementioned disadvantages, methods of forming alloy silicide containing nickel, titanium or cobalt have been attempted. For example, U.S. Pat. No. 6,468,901 discloses a method of forming a nickel silicide layer containing iridium by sequentially forming an iridium layer and a nickel layer on a silicon substrate. In addition, Japanese Laid-open Publication No. 2002-124487 discloses a method of forming a nickel suicide layer containing platinum.

However, considering that the silicide layer is required in the high performance MOS transistor of the ULSI semiconductor device, research on the silicide layer capable of overcoming the aforementioned disadvantages and the salicide process for forming the same have been continuously required.

### SUMMARY OF THE INVENTION

One embodiment of the invention provides a salicide process capable of increasing the annealing process margin without degradation of electrical characteristics.

Another embodiment of the invention provides a method of fabricating a semiconductor device capable of obtaining stable electrical characteristics using the salicide process.

In one aspect, the invention is directed to a salicide process using a bi-metal layer. The process includes forming a main metal layer on a semiconductor substrate containing silicon. A main metal alloy layer containing at least one species of alloy element is formed on the main metal layer. The semiconductor substrate having the main metal layer and the main metal alloy layer is annealed to form a main metal alloy silicide layer.

The main metal layer may be a nickel (Ni) layer, a cobalt (Co) layer or a titanium (Ti) layer. In addition, the at least one species of alloy element may be selected from a group consisting of tantalum (Ta), zirconium (Zr), iridium (Ir), ruthenium (Ru), rhodium (Rh), osmium (Os), chromium (Cr), titanium (Ti), hafnium (Hf), tungsten (W), cobalt (Co), platinum (Pt), palladium (Pd), vanadium (V), niobium (Nb) and molybdenum (Mo). According to an exemplary embodiment of the present invention, the main metal layer is a nickel layer, and the at least one species of alloy element is tantalum. In this case, the main metal alloy layer may be a nickel tantalum alloy layer. In one embodiment, the main metal layer and the main metal alloy layer are each formed to a thickness of about 5˜200 Å.

In another aspect, the invention is directed to a method of fabricating a semiconductor device using the salicide process. The method includes forming a MOS transistor in a predetermined region of a semiconductor substrate, wherein the MOS transistor has source and drain regions spaced apart from each other, a gate pattern formed on a channel region between the source and drain regions, and a spacer covering sidewalls of the gate pattern. A main metal layer is formed on an entire surface of the semiconductor substrate having the MOS transistor. A main metal alloy layer containing at least one species of alloy element is formed on the main metal layer. The semiconductor substrate having the main metal layer and the main metal alloy layer is annealed to form a main metal alloy silicide layer on at least the source and drain regions.

The main metal layer may be a nickel (Ni) layer, a cobalt (Co) layer or a titanium (Ti) layer. In addition, the at least one species of alloy element may be selected from a group consisting of tantalum (Ta), zirconium (Zr), iridium (Ir), ruthenium (Ru), rhodium (Rh), osmium (Os), chromium (Cr), titanium (Ti), hafnium (Hf), tungsten (W), cobalt (Co), platinum (Pt), palladium (Pd), vanadium (V), niobium (Nb) and molybdenum (Mo). According to an exemplary embodiment of the present invention, the main metal layer is a nickel layer, and the at least one species of alloy element is tantalum. In this case, the main metal alloy layer may be a nickel tantalum alloy layer. In one embodiment, the main metal layer and the main metal alloy layer are each formed to a thickness of about 5˜200 Å.

The gate pattern may be formed to have only a conductive gate electrode. In this case, the main metal alloy silicide layer is selectively formed on the gate electrode and the source and drain regions.

In addition, when the gate pattern is made of only the conductive gate electrode, before forming the main metal layer, a mask pattern covering the source and drain regions may be formed. The mask pattern is formed of an insulating layer. As a result, the main metal alloy silicide layer is selectively formed only on the gate electrode.

On the other hand, the gate pattern may be formed to have a gate electrode and a gate capping layer pattern, which are sequentially stacked. The gate capping layer pattern is formed of an insulating layer. In this case, the main metal alloy silicide layer is selectively formed only on the source and drain regions.

In one embodiment, forming the gate pattern comprises sequentially forming a conductive layer and an insulating layer on the semiconductor substrate and patterning the insulating layer and the conductive layer.

In one embodiment, an unreacted main metal layer and an unreacted main metal alloy layer remaining on the semiconductor substrate are removed, after forming the main metal alloy silicide layer. A capping layer may be formed on the main metal alloy layer before the annealing, the capping layer being removed together with the unreacted main metal layer and main metal alloy layer. The capping layer can be is formed of a titanium nitride layer.

In accordance with another aspect, the invention is directed to a method of fabricating a semiconductor device. According to the method, a MOS transistor is formed in a predetermined region of a semiconductor substrate, the MOS transistor having a a pair of source and drain regions spaced apart from each other, a gate pattern formed on a channel region between the pair of source and drain regions, and a spacer covering sidewalls of the gate pattern. A mask pattern covering the source and drain regions and exposing the gate pattern is formed on a surface of the semiconductor substrate having the MOS transistor. A main metal layer is formed on a surface of the semiconductor substrate having the mask pattern. A main metal alloy layer containing at least one species of alloy element is formed on the main metal layer. The semiconductor substrate having the main metal layer and the main metal alloy layer is annealed to selectively form a main metal alloy silicide layer on the gate pattern.

In one embodiment, the main metal layer is formed of a nickel (Ni) layer, a cobalt (Co) layer or a titanium (Ti) layer.

In one embodiment, the at least one species of alloy element includes tantalum (Ta), zirconium (Zr), iridium (Ir), ruthenium (Ru), rhodium (Rh), osmium (Os), chromium (Cr), titanium (Ti), hafnium (Hf), tungsten (W), cobalt (Co), platinum (Pt), palladium (Pd), vanadium (V), niobium (Nb) or molybdenum (Mo).

In one particular embodiment, the main metal layer is a nickel (Ni) layer, and the at least one species of alloy element is tantalum (Ta).

In one embodiment, the main metal layer and the main metal alloy layer are formed to a thickness of about 5˜200 Å.

### BRIEF DESCRIPTION OF THE DRAWINGS

The foregoing and other objects, features and advantages of the invention will be apparent from the more particular description of preferred aspects of the invention, as illustrated in the accompanying drawings in which like reference characters refer to the same parts throughout the different views. The drawings are not necessarily to scale, emphasis instead being placed upon illustrating the principles of the invention. In the drawings, the thickness of layers and regions are exaggerated for clarity. In addition, when a layer is described as being formed on another layer or on a substrate, the layer may be formed on the other layer or on the substrate, or a third layer may be interposed between the layer and the other layer or the substrate.

FIG. 1 is a process flow chart illustrating a salicide process and a method of fabricating a semiconductor device according to an embodiment of the present invention.

FIGS. 2 to 6 are cross-sectional views illustrating a salicide process and a method of fabricating a semiconductor device according to an embodiment of the present invention.

FIGS. 7 and 8 are cross-sectional views illustrating a method of fabricating a semiconductor device according to another embodiment of the present invention.

FIG. 9 is a graph of sheet resistance versus annealing temperature of a nickel silicide layer and a nickel-tantalum suicide layer formed by a conventional salicide process.

FIG. 10 is a graph showing drain-off current characteristics of NMOS transistors having a conventional nickel silicide layer and a conventional nickel-tantalum silicide layer.

FIG. 11 is a graph showing changes of sheet resistances depending upon silicidation annealing temperatures of nickel-tantalum silicide layers according to an embodiment of the present invention and silicide layers according to a comparative example.

FIGS. 12a to 12e are scanning electron microscope (SEM) images showing surface morphology of nickel-tantalum silicide layers according to an embodiment of the present invention and silicide layers according to a comparative example.

FIG. 13 is a graph of sheet resistance versus annealing temperature of nickel-tantalum silicide layers according to an embodiment of the present invention and silicide layers according to a comparative example.

FIG. 14 is a graph showing resistance characteristics of an N-type impurity region having a nickel-tantalum silicide layer according to embodiments of the present invention and an N-type impurity region having a silicide layer according to a comparative example.

FIG. 15 is a graph showing resistance characteristics of a polysilicon electrode having a nickel-tantalum silicide layer according to embodiments of the present invention and a polysilicon electrode having a silicide layer according to a comparative example.

FIG. 16 is a graph showing drain-off current characteristics of NMOS transistors according to an embodiment of the present invention and conventional NMOS transistors according to a comparative example.

### DETAILED DESCRIPTION OF THE INVENTION

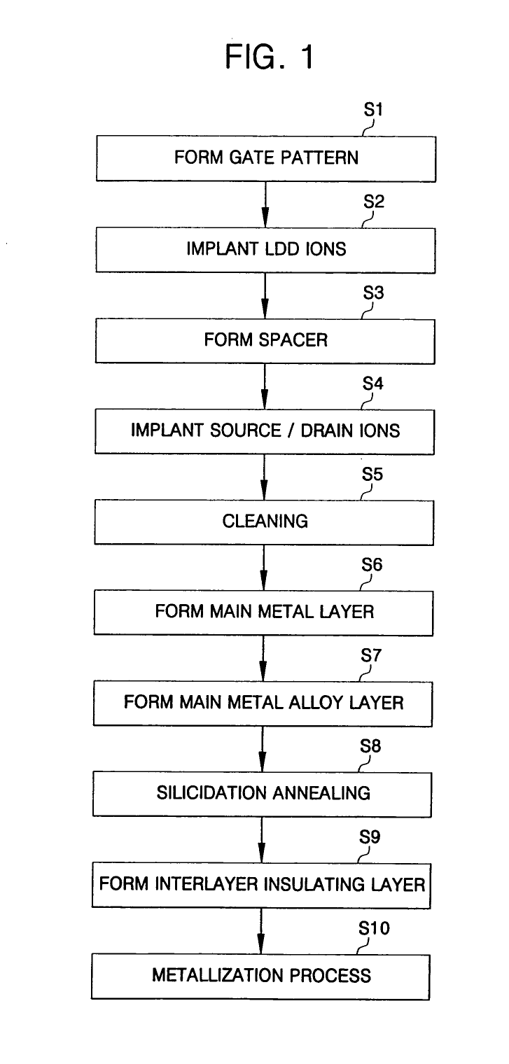

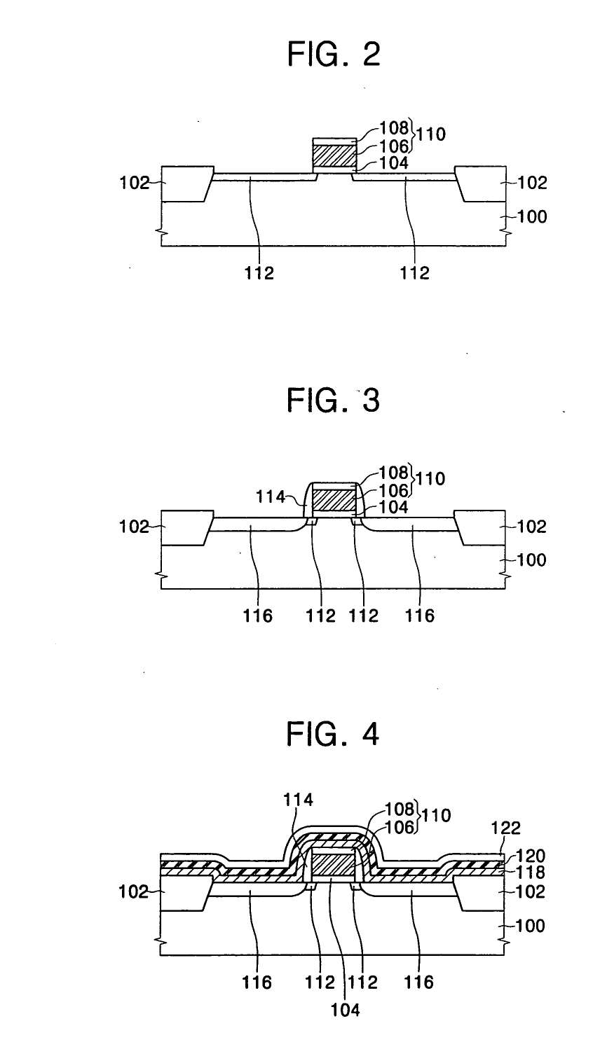

FIG. 1 is a process flow chart illustrating a salicide process and a method of fabricating a semiconductor device using the same according to an embodiment of the present invention. In addition, FIGS. 2 to 6 are cross-sectional views illustrating a salicide process and a method of fabricating a semiconductor device using the same according to an embodiment of the present invention.

Referring to FIGS. 1 and 2, an isolation layer 102 is formed in a predetermined region of a semiconductor substrate 100 to define an active region. The semiconductor substrate 100 may be a silicon substrate or a silicon-on-insulator (SOI) substrate. A gate insulating layer is formed on the active region. A gate conductive layer and a gate capping layer are sequentially formed on an entire surface of the semiconductor substrate having the gate insulating layer. The gate conductive layer may be formed of a silicon layer such as a polysilicon layer. The silicon layer may be doped with N-type impurities or P-type impurities. Alternatively, the gate conductive layer may be formed by sequentially depositing a silicon layer and a tungsten silicide layer. In addition, the gate capping layer is formed of an insulating layer such as a silicon oxide layer or a silicon nitride layer. A process of forming the gate capping layer may be omitted.

Next, the gate capping layer and the gate conductive layer are patterned to form a gate pattern 110 crossing over the active region (S1 in FIG. 1). As a result, the gate pattern 110 includes a gate electrode 106 and a gate capping layer pattern 108, which are sequentially stacked. When the gate conductive layer is formed of only a silicon layer, the gate electrode 106 is made of only a silicon layer pattern. Alternatively, when the gate conductive layer is formed by sequentially depositing a silicon layer and a tungsten silicide layer, the gate electrode 106 includes a silicon layer pattern and a tungsten silicide layer pattern, which are sequentially stacked. However, when the formation of the gate capping layer is omitted, the gate pattern 110 is composed of only the gate electrode 106. The gate insulating layer may be patterned while forming the gate pattern 110. As a result, as shown in FIG. 2, a gate insulating layer pattern 104 is formed between the gate pattern 110 and the active region. First impurity ions are implanted into the active region to form lightly doped drain (LDD) regions 112 using the gate pattern 110 and the isolation layer 102 as ion implantation masks (S2 in FIG. 1). The first impurity ions may be N-type impurity ions or P-type impurity ions.

Referring to FIGS. 1 and 3, a spacer insulating layer is formed on an entire surface of the semiconductor substrate having the LDD regions 112. The spacer insulating layer may be formed of a silicon nitride layer. The spacer insulating layer is anisotropically etched to form a spacer 114 on sidewalls of the gate pattern 110 (S3 in FIG. 1). Second impurity ions are implanted into the active region to form source/drain regions 116 using the gate pattern 110, the spacer 114 and the isolation layer 102 as ion implantation masks (S4 in FIG. 1). As a result, the LDD regions 112 remain under the spacer 114. The second impurity ions also may be N-type impurity ions or P-type impurity ions, and have the same conductivity type as the first impurity ions. Next, the semiconductor substrate having the source/drain regions 116 is annealed to activate the impurity ions in the source/drain regions 116. The gate pattern 110, the gate insulating layer 104, the source/drain regions 116 and the spacer 114 constitute a MOS transistor.

Referring to FIGS. 1 and 4, a cleaning process is performed to remove a native oxide layer and contaminating particles remaining on the source/drain regions 116 (S5 in FIG. 1). A main metal layer 118 is formed on an entire surface of the semiconductor substrate (S6 in FIG. 1). The main metal layer 118 may be formed of a nickel layer, a cobalt layer or a titanium layer. Preferably, the main metal layer 118 may be formed of a nickel layer. Preferably, the main metal layer 118 has a thickness of about 5˜200 Å. A main metal alloy layer 120 is formed on the main metal layer 118 (S7 in FIG. 1). The main metal alloy layer includes a metal constituting the main metal layer 118 and at least one species of alloy element. The at least one species of alloy element may be at least one of tantalum (Ta), zirconium (Zr), iridium (Ir), ruthenium (Ru), rhodium (Rh), osmium (Os), chromium (Cr), titanium (Ti), hafnium (Hf), tungsten (W), cobalt (Co), platinum (Pt), palladium (Pd), vanadium (V), niobium (Nb) and molybdenum (Mo). Preferably, the at least one species of alloy element may be tantalum, in this case, the main metal alloy layer 120 may be a nickel-tantalum alloy layer. Preferably, the main metal alloy layer 120 has a thickness of about 5˜200 Å. According to an exemplary embodiment of the present invention, the main metal layer 118 may be formed of a nickel layer, and the main metal alloy layer 120 may be formed of a nickel-tantalum alloy layer. After forming the main metal alloy layer 120, a capping layer 122 is formed on the main metal alloy layer 120. The capping layer 122 may be formed of a titanium nitride (TiN) layer. The capping layer 122 is formed to prevent the main metal layer 118 and the main metal alloy layer 120 from being oxidized. However, a process of forming the capping layer 122 may be omitted.

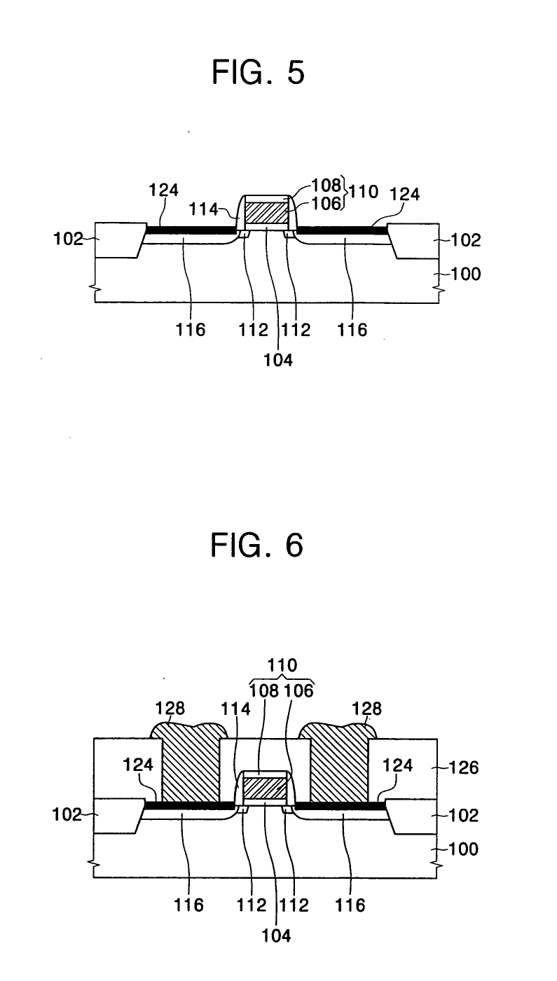

Referring to FIGS. 1 and 5, a silicidation annealing is applied to the semiconductor substrate having the main metal layer 118, the main metal alloy layer 120 and the capping layer 122 (S8 in FIG. 1). A temperature of the silicidation annealing may be varied depending upon a metal element constituting the main metal layer 118. When the main metal layer 118 is formed of a nickel layer, the silicidation annealing may be performed at a temperature of about 300˜600° C. During the silicidation annealing, the main metal layer 118 and the main metal alloy layer 120 are reacted with silicon atoms in the source/drain regions 116. As a result, as shown in FIG. 5, main metal alloy silicide layers 124 are formed on surfaces of the source/drain regions 116.

According to an exemplary embodiment of the present invention, a nickel layer and a nickel-tantalum alloy layer are sequentially formed, and the silicidation annealing is performed, thereby forming a nickel-tantalum silicide layer. At this time, thermal stability of the nickel-tantalum silicide layer may be improved by the tantalum added as an alloy element. In addition, the nickel layer is primarily formed, and then the nickel-tantalum alloy layer is formed on the nickel layer, so that the tantalum content in the nickel-tantalum silicide layer is higher at an upper portion of the nickel-tantalum silicide layer than a lower portion of the nickel-tantalum silicide layer. As a result, as lateral growth of the nickel-tantalum silicide layer in the source/drain regions 116 is minimized, it is possible to prevent electrical characteristics of the semiconductor substrate from degrading.

As described above, when the gate pattern 110 includes a gate electrode 106 and a gate capping layer pattern 108, as shown in FIG. 5, the main metal alloy silicide layers 124 are selectively formed only on the source/drain regions 116.

When the gate pattern is made of only the gate electrode 106 and the gate electrode 106 is made of only a silicon layer pattern, during the silicidation annealing process, another main metal alloy silicide layer (not shown) having the same material structure as the main metal alloy silicide layers 124 is formed on the gate electrode 106 made of the silicon layer pattern.

Subsequently, unreacted main metal layer and main metal alloy layer on the spacer 114, the isolation layer 102 and the gate capping layer pattern 108 are removed. The unreacted main metal layer and main metal alloy layer may be removed, for example, using a mixture of sulfuric acid (H₂SO₄) and hydrogen peroxide (H₂O₂). While removing the unreacted main metal layer and main metal alloy layer, the capping layer 122 also may be stripped.

Referring to FIGS. 1 and 6, an interlayer insulating layer 126 is formed on an entire surface of the semiconductor substrate having the main metal alloy silicide layers 124 (S9 in FIG. 1). The interlayer insulating layer 126 is patterned to form contact holes exposing the main metal alloy silicide layers 124 on the source/drain regions 116. A metal layer is formed on the semiconductor substrate having the contact holes, and the metal layer is patterned to form metal wires 128 filling the contact holes (S10 in FIG. 1).

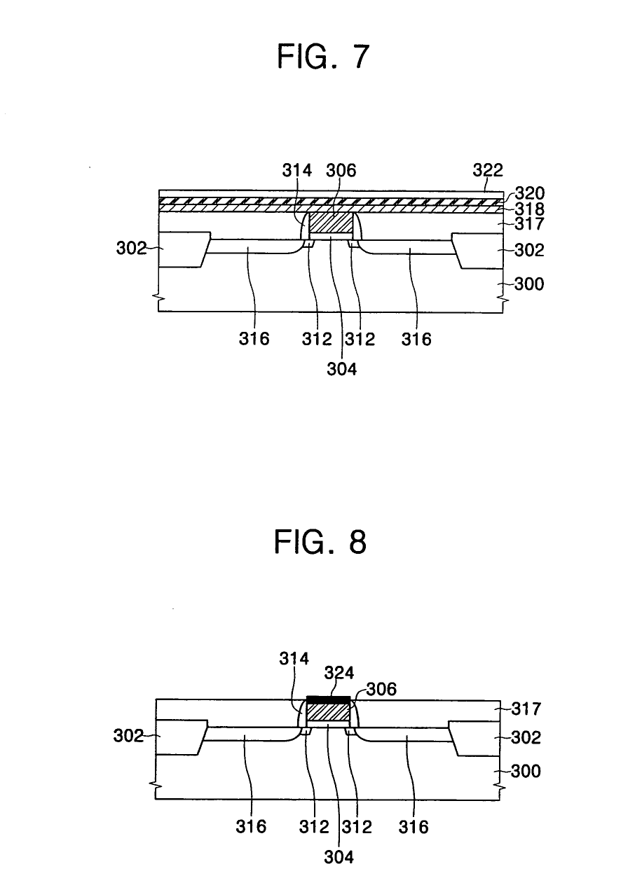

FIGS. 7 and 8 are cross-sectional views illustrating a method of fabricating a semiconductor substrate according to another embodiment of the present invention.

Referring to FIG. 7, a MOS transistor is formed using the same method as described in FIGS. 2 and 3. That is, an isolation layer 302 is formed in a semiconductor substrate 300 to define an active region, and a gate insulating layer pattern 304 and a gate electrode 306 are formed on the active region. Then, LDD regions 312, a spacer 314 and source/drain regions 316 are formed. According to the embodiment of the present invention, a gate pattern of the MOS transistor is formed to have only the gate electrode 306 made of a silicon layer pattern. Next, a mask insulating layer is formed on an entire surface of the semiconductor substrate having the MOS transistor. Preferably, the mask insulating layer is formed of an insulating layer having an etch selectivity with respect to the gate electrode 306. For example, the mask insulating layer may be formed of a silicon oxide layer. The mask insulating layer is planarized to form a mask pattern 317 exposing the gate electrode 306. As a result, at least the source/drain regions 316 are covered with the mask pattern 317.

A main metal layer 318, a main metal alloy layer 320 and a capping layer 322 are sequentially formed on an entire surface of the semiconductor substrate having the exposed gate electrode 306. The main metal layer 318 and the main metal alloy layer 320 are formed of the same material layer as described in FIG. 4, and the capping layer 322 is also formed of the same material layer as the capping layer 122 in FIG. 4. A process of forming the capping layer 322 may be omitted.

Referring to FIG. 8, next, a silicidation annealing is applied to the semiconductor substrate having the main metal layer 318, the main metal alloy layer 320 and the capping layer 322. The silicidation process is performed using the same method as described in FIG. 5. As a result, a main metal alloy silicide layer 324 is selectively formed only on the gate electrode 306. Subsequently, while not shown, a metallization process is applied to the semiconductor substrate including the main metal alloy silicide layer 324. The metallization process is performed using the same method as described in FIG. 6.

### EXAMPLES

Hereinafter, various measured results of samples fabricated according to the aforementioned embodiments of the present invention and samples according to comparative examples will be described.

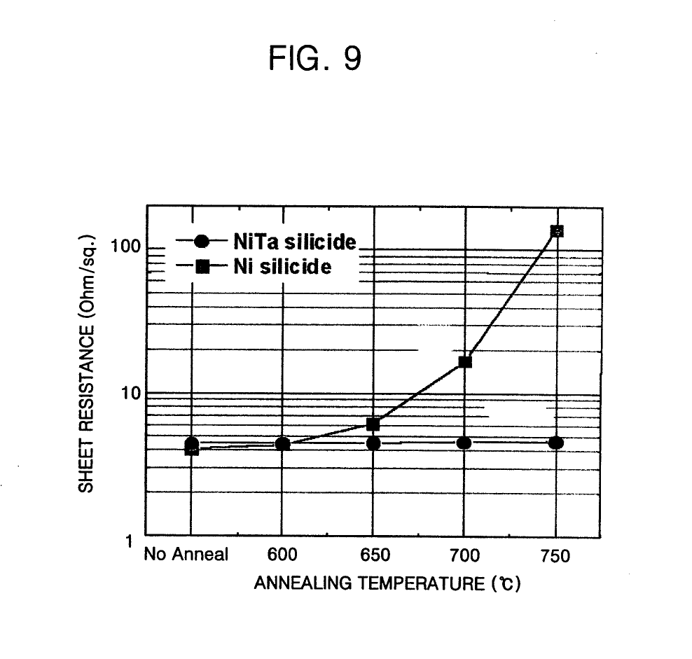

FIG. 9 is a graph of sheet resistance versus annealing temperature of a nickel silicide layer and a nickel-tantalum silicide layer formed by a conventional salicide process.

The nickel silicide layer and the nickel-tantalum silicide layer were directly formed on the silicon substrates using a single nickel layer and a single nickel-tantalum alloy layer. That is, the single nickel layer and the single nickel-tantalum alloy layer were respectively formed on the silicon substrate, and annealed for about 30 seconds at a temperature of about 450° C. As a result, the nickel silicide layer and the nickel-tantalum silicide layer were formed on the silicon substrate. The nickel silicide layer and the nickel-tantalum silicide layer were additionally annealed at room temperature to 750° C. The additional annealing process was performed for about 30 seconds using a rapid thermal process (RTP).

Referring to FIG. 9, the nickel-tantalum silicide layer showed uniform sheet resistance characteristics in an additional annealing temperature range of room temperature to 750° C. Specifically, the nickel-tantalum silicide layer showed a uniform sheet resistance of about 4.5 ohm/sq. even after the additional annealing process performed at the temperature of 750° C. On the other hand, the conventional nickel silicide layer showed unstable sheet resistance characteristics at an additional annealing temperature higher than 600° C. That is, the conventional nickel silicide layer showed a high sheet resistance of about 100 ohm/sq. after the additional annealing process performed at a temperature of 750° C.

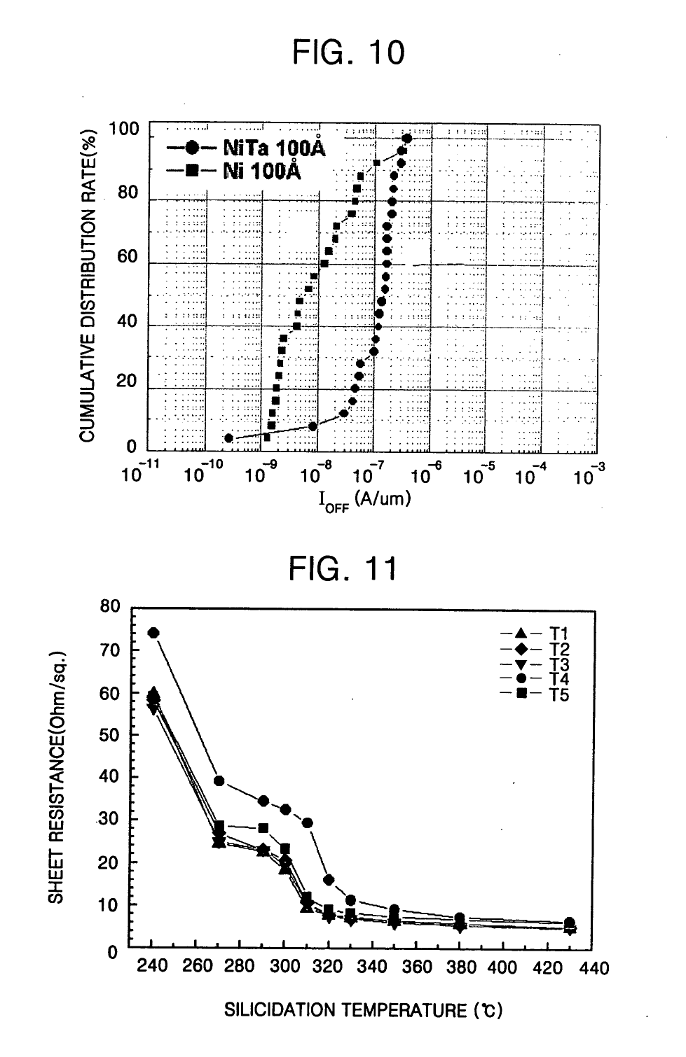

FIG. 10 is a graph showing drain-off current characteristics of NMOS transistors having a conventional nickel silicide layer and a conventional nickel-tantalum silicide layer.

The nickel silicide layer and the nickel-tantalum silicide layer were formed on source/drain regions and the gate electrodes of the NMOS transistor by performing the silicidation annealing as described in FIG. 9. In this case, a single nickel layer with a thickness of 100 Å was used to form the nickel silicide layer, while a single nickel-tantalum alloy layer with a thickness of 100 Å was used to form the nickel-tantalum silicide layer.

Referring to FIG. 10, the NMOS transistors having the nickel-tantalum silicide layer represented a drain off current higher than the NMOS transistors having the nickel silicide layer by about 1˜2 order. This result is due to lateral growth in the source/drain regions of the nickel-tantalum silicide layer, that is, encroachment into a channel region.

When the nickel-tantalum silicide layer is formed, these results represent that it is possible to obtain improved thermal stability in comparison with the nickel silicide layer. However, it represented that the nickel-tantalum silicide layer formed by the single nickel-tantalum alloy layer degrades electrical characteristics of the MOS transistor due to the lateral growth of the silicide layer.

FIGS. 11 to 13 are results showing various characteristics of nickel-tantalum silicide layers according to an embodiment of the present invention and silicide layers according to a comparative example. In FIGS. 11 to 13, after forming a bi-metal layer of a nickel layer and a nickel-tantalum alloy layer on the silicon substrate, nickel-tantalum silicide layers according to the embodiment of the present invention were formed by a silicidation annealing process. At this time, the nickel layer and the nickel-tantalum alloy layer were formed to a thickness of 30 Å/70 Å(T1), 50 Å/50 Å(T2) and 70 Å/30 Å(T3), respectively. In addition, for the sake of comparison, a nickel-tantalum silicide layer T4 and a nickel silicide layer T5 using a single metal layer were formed, respectively. In the comparative example, each of the nickel layer and the nickel-tantalum alloy layer for forming a silicide layer was formed to a thickness of 100 Å.

FIG. 11 is a graph showing changes of sheet resistances depending upon silicidation annealing temperatures of nickel-tantalum silicide layers T1, T2 and T3 according to an embodiment of the present invention and silicide layers T4 and T5 according to a comparative example.

Referring to FIG. 11, even though silicidation annealing was preformed at a low temperature of about 300° C. or less, the nickel-tantalum silicide layers according to the embodiment of the present invention represented sheet resistance characteristics similar to the nickel silicide layer (T5), and represented low sheet resistance in comparison with the nickel-tantalum silicide layer T4 formed using the single nickel-tantalum alloy layer.

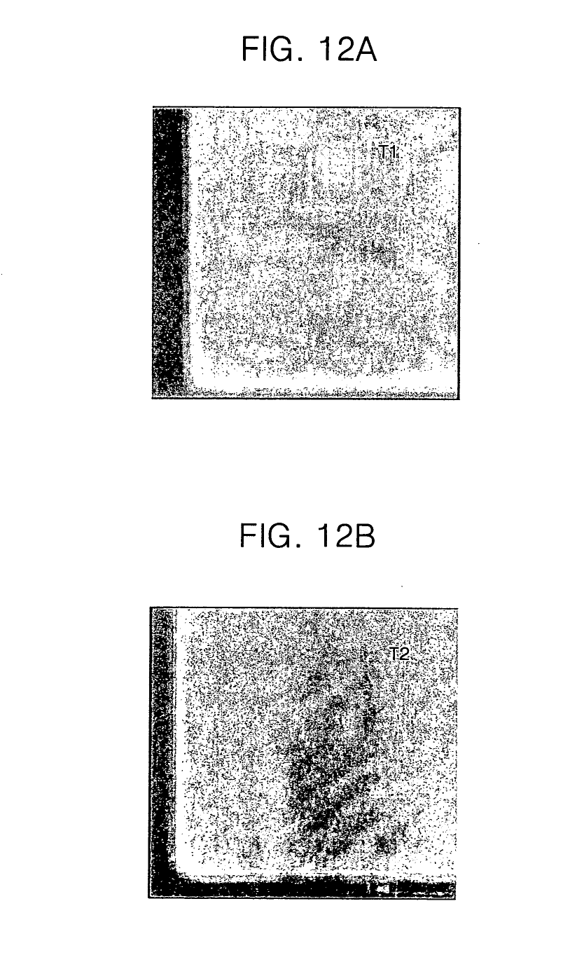

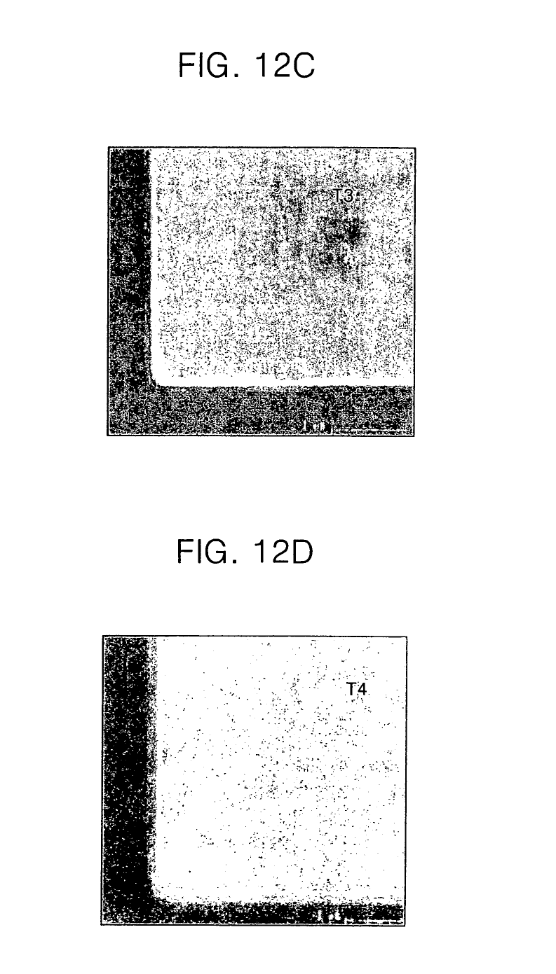

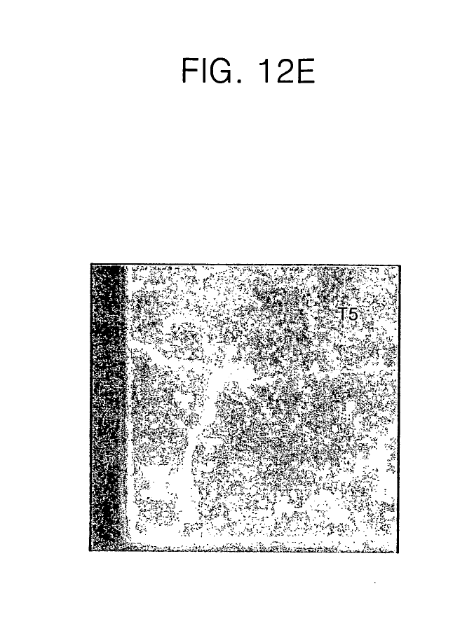

FIGS. 12A to 12E are scanning electron microscope (SEM) images showing surface morphology of nickel-tantalum silicide layers T1, T2 and T3 according to an embodiment of the present invention and silicide layers T4 and T5 according to a comparative example.

Referring to FIGS. 12A to 12E, surface morphology of the nickel-tantalum silicide layer T4 and the nickel silicide layer T5 formed by the conventional salicide process using a single layer represented uneven surface morphology as shown in FIGS. 12D and 12E respectively, in particular, the nickel silicide layer T5 represented extreme unevenness. This surface morphology represents that an interface between the silicon substrate and the silicide layer is uneven when the suicide layers T4 and T5 are actually applied to a MOS transistor. As shown in FIGS. 12D and 12E, the unevenness of the interface causes thermal instability, thereby making agglomeration of the silicide layer more extreme. In addition, there is a high possibility of junction leakage current at a junction interface. On the other hand, the nickel-tantalum silicide layers T1, T2 and T3 represented even surface morphology as shown in FIGS. 12A to 12C. This result represents that the even interface between the silicon substrate and the silicide layer may be obtained in the case of forming the silicide layer using a bi-metal layer as the embodiment of the present invention in comparison with the case of forming the silicide layer using a single metal layer.

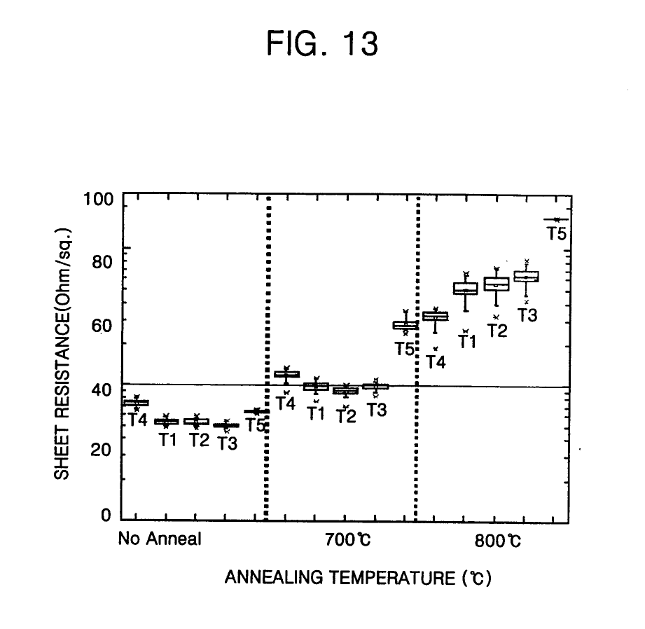

FIG. 13 is a graph of sheet resistance versus annealing temperature of nickel-tantalum silicide layers T1, T2 and T3 according to an embodiment of the present invention and silicide layers T4 and T5 according to a comparative example. In the graph of FIG. 13, the abscissa represents an additional annealing temperature, and the ordinate represents sheet resistance. The additional annealing processes were performed for about 30 seconds using a rapid thermal process at room temperature, 700° C. and 800° C.

Referring to FIG. 13, as a result of performing the additional annealing process at a temperature of 700° C. or more, it represented that sheet resistance of the nickel silicide layer T5 was rapidly increased. However, the nickel-tantalum suicide layers T1, T2 and T3 according to the embodiment of the present invention represented a slight increase of the sheet resistance depending upon the additional annealing process and more stable thermal characteristics in comparison with the nickel silicide layer T5.

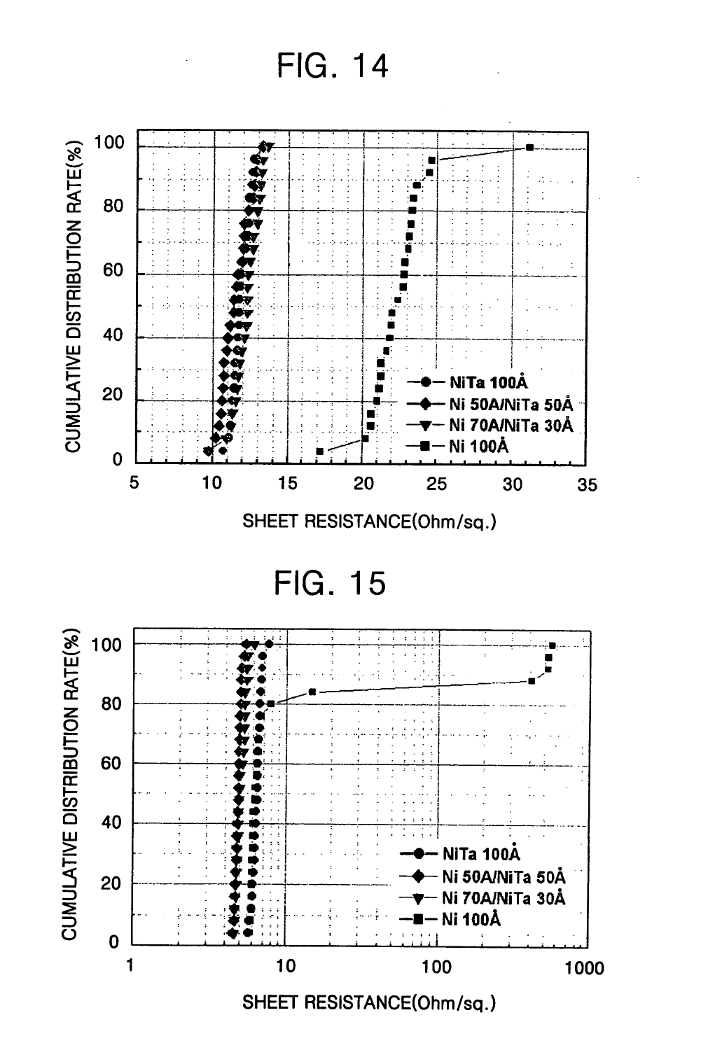

FIG. 14 is a graph showing resistance characteristics of an N-type impurity region having a nickel-tantalum silicide layer according to embodiments of the present invention and an N-type impurity region having a silicide layer according to a comparative example.

In FIG. 14, the silicide layers were formed on N-type impurity regions formed in the semiconductor substrate. The N-type impurity regions were formed by implanting arsenic ions into the semiconductor substrate. In the case of the embodiments according to the present invention, a bi-metal layer of a nickel layer and a nickel-tantalum alloy layer was formed on the semiconductor substrate having the N-type impurity regions, and silicidation annealing was performed to form a nickel-tantalum silicide layer. At this time, the nickel layer and the nickel-tantalum alloy layer constituting the bi-metal layer were formed to a thickness of about 50 Å/50 Å and 70 Å/30 Å, respectively. In the case of the comparative example, a single nickel layer or a single nickel-tantalum alloy layer was formed on the semiconductor substrate having the N-type impurity regions, and then the silicidation annealing was performed to form a nickel silicide layer or a nickel-tantalum silicide layer. At this time, the nickel layer or the nickel-tantalum alloy layer was formed to a thickness of about 100 Å.

Referring to FIG. 14, the N-type impurity regions having the nickel-tantalum silicide layer according to the embodiment of the present invention represented uniform sheet resistance values of about 9 ohm/sq.˜14 ohm/sq. On the other hand, the N-type impurity regions having the nickel silicide layer according to the comparative example represented high and non-uniform sheet resistance values of about 17 ohm/sq.˜31 ohm/sq.

FIG. 15 is a graph showing resistance characteristics of a polysilicon electrode having a nickel-tantalum silicide layer according to embodiments of the present invention and a polysilicon electrode having a silicide layer according to a comparative example. In FIG. 15, the polysilicon electrodes were doped with arsenic ions, in the embodiments according to the present invention and the comparative example, the conditions of forming the silicide layer on the polysilicon electrodes are the same as described in FIG. 14.

Referring to FIG. 15, the polysilicon electrode having the nickel-tantalum silicide layer according to the embodiment of the present invention represented low and uniform sheet resistance values of about 4 ohm/sq.˜6 ohm/sq. On the other hand, the polysilicon electrode having the nickel silicide layer according to the comparative example represented high and non-uniform sheet resistance values of about 6 ohm/sq.˜600 ohm/sq.

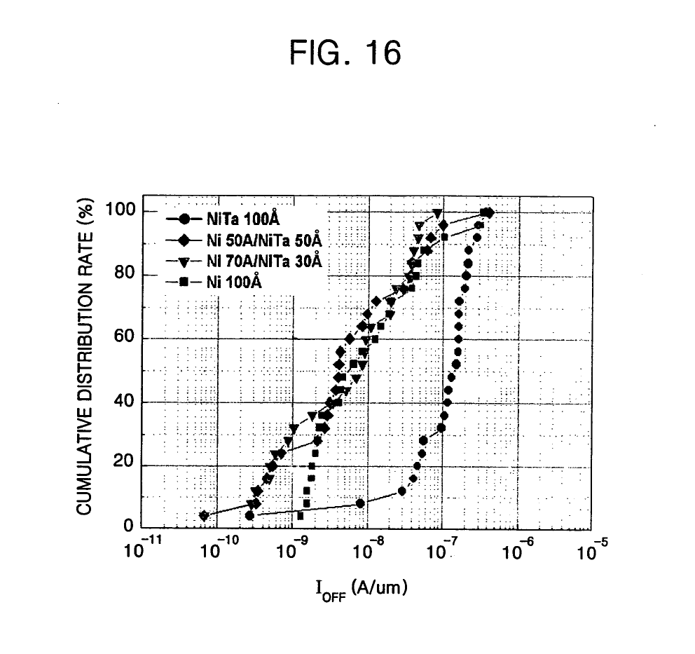

FIG. 16 is a graph showing drain-off current characteristics of NMOS transistors according to an embodiment of the present invention and conventional NMOS transistors according to a comparative example.

In FIG. 16, NMOS transistors according to the embodiment of the present invention were formed to have a nickel-tantalum silicide layer formed using a bi-metal layer. That is, after fabricating the NMOS transistor as described in FIGS. 2 to 3, the bi-metal layer of a nickel layer and a nickel-tantalum layer was formed on the substrate having the NMOS transistor. Then, the silicidation annealing was performed to form a nickel-tantalum silicide layer on source/drain regions and a gate electrode of the NMOS transistor. At this time, the nickel layer and the nickel-tantalum alloy layer constituting the bi-metal layer were formed to a thickness of about 50 Å/50 Å and 70 Å/30 Å, respectively.

In the meantime, NMOS transistors according to the comparative example were formed to have a nickel-silicide layer or a nickel-tantalum silicide layer formed using a single layer. That is, after forming the NMOS transistor as described in FIGS. 2 and 3, a single nickel layer or a single nickel-tantalum alloy layer was formed on the substrate having the NMOS transistor. Then, silicidation annealing was performed to form a nickel silicide layer or a nickel-tantalum silicide layer on source/drain regions and a gate electrode of the NMOS transistor. At this time, each of the nickel layer and the nickel-tantalum alloy layer was formed to a thickness of about 100 Å.

Referring to FIG. 16, the NMOS transistors having the nickel-tantalum silicide layer according to the embodiment of the present invention represented a drain off current lower than that of the conventional NMOS transistor having the nickel-tantalum silicide layer formed using the single nickel-tantalum alloy layer and similar to that of the conventional NMOS transistor having the nickel silicide layer. The reason for this result is that the nickel-tantalum silicide layer according to the embodiment of the present invention has a higher content of tantalum added as an alloy element in an upper portion of the nickel-tantalum silicide layer than a lower portion of the nickel-tantalum silicide layer by forming a bi-metal layer of a nickel layer and a nickel-tantalum alloy layer and then performing the silicidation annealing. That is, this is because lateral growth of the nickel-tantalum silicide layer by tantalum in the source/drain regions of the NMOS transistor becomes minimized.

In conclusion, in the case of forming a bi-metal layer of a nickel layer and a nickel-tantalum alloy layer and then performing the silicidation annealing to form the nickel-tantalum silicide layer according to the present invention, a thermal instability problem, which has become a problem in the conventional nickel silicide layer, may be improved upon by tantalum added as an alloy element. In addition, as the content of tantalum in the lower portion of the nickel-tantalum silicide layer becomes low, the lateral growth of the nickel-tantalum silicide layer in the source/drain regions of the transistor may be suppressed. As a result, the present invention is capable of obtaining improved electrical characteristics in comparison with the nickel-tantalum silicide layer formed of the conventional single nickel-tantalum alloy layer.

As can be seen from the foregoing, the present invention is capable of remarkably improving thermal stability and minimizing degradation of electrical characteristics of an alloy silicide layer by forming the alloy silicide layer using a bi-metal layer of a main metal layer and a main metal alloy layer.

Preferred embodiments of the present invention have been disclosed herein and, although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A salicide process comprising:
forming a main metal layer on a semiconductor substrate containing silicon;
forming a main metal alloy layer containing at least one species of alloy element on the main metal layer; and
annealing the semiconductor substrate having the main metal layer and the main metal alloy layer to form a main metal alloy silicide layer.

2. The salicide process according to claim 1, wherein the main metal layer comprises a layer selected from the group consisting of a nickel (Ni) layer, a cobalt (Co) layer and a titanium (Ti) layer.

3. The salicide process according to claim 2, wherein the at least one species of alloy element includes a material selected from a group consisting of tantalum (Ta), zirconium (Zr), iridium (Ir), ruthenium (Ru), rhodium (Rh), osmium (Os), chromium (Cr), titanium (Ti), hafnium (Hf), tungsten (W), cobalt (Co), platinum (Pt), palladium (Pd), vanadium (V), niobium (Nb) and molybdenum (Mo).

4. The salicide process according to claim 3, wherein the main metal layer is a nickel (Ni) layer.

5. The salicide process according to claim 4, wherein the at least one species of alloy element is tantalum (Ta).

6. The salicide process according to claim 1, wherein the main metal layer and the main metal alloy layer are formed to a thickness of about 5˜200 Å.

7. A method of fabricating a semiconductor device, comprising:
forming a MOS transistor in a predetermined region of a semiconductor substrate, the MOS transistor having source and drain regions spaced apart from each other, a gate pattern formed on a channel region between the source and drain regions, and a spacer covering sidewalls of the gate pattern;
forming a main metal layer on a surface of the semiconductor substrate having the MOS transistor;
forming a main metal alloy layer containing at least one species of alloy element on the main metal layer; and
annealing the semiconductor substrate having the main metal layer and the main metal alloy layer to form a main metal alloy silicide layer on at least the source and drain regions.

8. The method according to claim 7, wherein the main metal layer comprises a layer selected from the group consisting of a nickel (Ni) layer, a cobalt (Co) layer and a titanium (Ti) layer.

9. The method according to claim 8, wherein the at least one species of alloy element includes a material selected from a group consisting of tantalum (Ta), zirconium (Zr), iridium (Ir), ruthenium (Ru), rhodium (Rh), osmium (Os), chromium (Cr), titanium (Ti), hafnium (Hf), tungsten (W), cobalt (Co), platinum (Pt), palladium (Pd), vanadium (V), niobium (Nb) and molybdenum (Mo).

10. The method according to claim 9, wherein the main metal layer is a nickel (Ni) layer.

11. The method according to claim 10, wherein the at least one species of alloy element is tantalum (Ta).

12. The method according to claim 7, wherein the main metal layer and the main metal alloy layer are formed to a thickness of about 5˜200 Å.

13. The method according to claim 7, wherein forming the gate pattern comprises:
forming a silicon layer on the semiconductor substrate; and
patterning the silicon layer, the patterned silicon layer and the main metal layer and the main metal alloy layer formed thereon being reacted with each other during the annealing to form a gate main metal alloy silicide layer.

14. The method according to claim 7, wherein forming the gate pattern comprises:
sequentially forming a conductive layer and an insulating layer on the semiconductor substrate; and
patterning the insulating layer and the conductive layer.

15. The method according to claim 7, further comprising removing an unreacted main metal layer and an unreacted main metal alloy layer remaining on the semiconductor substrate, after forming the main metal alloy silicide layer.

16. The method according to claim 15, further comprising forming a capping layer on the main metal alloy layer before the annealing, the capping layer being removed together with the unreacted main metal layer and main metal alloy layer.

17. The method according to claim 16, wherein the capping layer is formed of a titanium nitride layer.

18. A method of fabricating a semiconductor device, comprising:
forming a MOS transistor in a predetermined region of a semiconductor substrate, the MOS transistor having source and drain regions spaced apart from each other, a gate pattern formed on a channel region between the source and drain regions, and a spacer covering sidewalls of the gate pattern;
forming a mask pattern covering the source and drain regions and exposing the gate pattern on a surface of the semiconductor substrate having the MOS transistor;
forming a main metal layer on a surface of the semiconductor substrate having the mask pattern;
forming a main metal alloy layer containing at least one species of alloy element on the main metal layer; and
annealing the semiconductor substrate having the main metal layer and the main metal alloy layer to selectively form a main metal alloy silicide layer on the gate pattern.

19. The method according to claim 18, wherein the main metal layer comprises a layer selected from the group consisting of a nickel (Ni) layer, a cobalt (Co) layer and a titanium (Ti) layer.

20. The method according to claim 19, wherein the at least one species of alloy element includes a material selected from a group consisting of tantalum (Ta), zirconium (Zr), iridium (Ir), ruthenium (Ru), rhodium (Rh), osmium (Os), chromium (Cr), titanium (Ti), hafnium (Hf), tungsten (W), cobalt (Co), platinum (Pt), palladium (Pd), vanadium (V), niobium (Nb) and molybdenum (Mo).

21. The method according to claim 20, wherein the main metal layer is a nickel (Ni) layer.

22. The method according to claim 21, wherein the at least one species of alloy element is tantalum (Ta).

23. The method according to claim 18, wherein the main metal layer and the main metal alloy layer are formed to a thickness of about 5˜200 Å.
